(19) United States
(12) Patent Application Publication
(10) Pub. No.: US 2026/0223572 A1
(43) Pub. Date: Jul. 30, 2026

(54) DISPLAY DEVICE

(71) Applicant: LG Display Co., Ltd., Seoul (KR)

(72) Inventors: Jeongmin PARK, Paju-si (KR); Daegyu JO, Seoul (KR)

(73) Assignee: LG Display Co., Ltd., Seoul (KR)

(21) Appl. No.: 19/410,324

(22) Filed: Dec. 5, 2025

(30) Foreign Application Priority Data
Jan. 24, 2025 (KR) 10-2025-0011501

(51) Int. Cl. H10K 59/80; H10K 59/40; H10K 59/35; H10K 102/00

(52) U.S. Cl. CPC H10K 59/873; H10K 59/40; H10K 59/35; H10K 2102/311

(57) ABSTRACT

A display device includes a substrate, a display area disposed on the substrate, and a non-display area having a first area surrounding an outer side of the display area and a second area disposed on one side of the display area. A bendable area is disposed in the second area, and a lower corner area extends from the first area of the non-display area to the bendable area and includes a lower corner end. A plurality of structures is disposed in the lower corner area and spaced apart from each other. At least one of the plurality of structures is disposed with a spacing from the lower corner end to define a gap. This arrangement controls material continuity in the lower corner area and assists in protecting components located adjacent to the bendable area.

### CROSS-REFERENCE TO RELATED APPLICATION

The present application claims priority to Korean Patent Application No. 10-2025-0011501, filed on January 24, 2025, the entire contents of which is incorporated herein for all purposes by this reference.

### BACKGROUND

### Technical Field

The present disclosure relates to a display device.

### Description of Related Art

A display device is applied to various electronic devices such as a TV, a smartphone, a laptop computer, and a tablet. To this end, research is being conducted to develop a thin, light weight, and low power consuming display device

Examples of the display device include a LCD (Liquid Crystal Display) device, a FED (Field Emission Display) device, and an OLED (Organic Light-emitting Display) device.

A bezel area of the display device may include an area surrounding an outer side of a display area of the display panel. The bezel area may protect edges of the display panel and internal electronic components from external impact, pressure, or external damage. The bezel area may be visually recognized by a user and thus may be a factor that degrades a sense of immersion in an image emitted from the display area.

### BRIEF SUMMARY

As a flexible substrate made of a flexible material is applied to the display device, the display panel may include a bendable area that is bent to hide a pad area under the display area. The bendable area may extend from a link area on a lower side in a plan view of the display area of the display panel.

In this case, the bezel area may include upper, left, and right sides in a plan view of the display panel and the lower corner side of the display panel. The bendable area extends from the link area on the lower side of the display area of the display panel. In the bezel area, protective layers having a multilayer structure may be disposed to protect the edge of the display panel and the internal constituent circuits from external impact, pressure, or external damage. The protective layers may include an inorganic insulating material or an organic insulating material.

However, when the organic insulating material is damaged by an external impact or the like, moisture may penetrate through the organic insulating material. When the moisture penetrates into the organic insulating material, a line such as a signal line including a metal material is corroded.

Accordingly, through various experiments, the inventors of the present disclosure have invented a display device capable of preventing external moisture from penetrating through the organic insulating material in a non-display area.

A technical purpose according to an embodiment of the present disclosure is to provide a display device capable of preventing lines disposed in a non-display area from being damaged due to the moisture penetration.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device in accordance with one embodiment of the present disclosure includes: a substrate; a display area disposed on the substrate; a non-display area including a first area surrounding an outer side of the display area and a second area disposed on one side of the display area; a bendable area disposed in the second area; a lower corner area extending from the first area of the non-display area to the bendable area and including a lower corner end ; and a plurality of structures disposed spaced apart from each other in the lower corner area, wherein one of the plurality of structures is disposed with a spacing from the lower corner end of the lower corner area by a gap.

According to an embodiment of the present disclosure, the display device may include the plurality of structures disposed in the lower corner area adjacent to the bendable area in the non-display area of the substrate, and spaced apart from each other in the plan view of the display device. The outermost one of the plurality of structures may be spaced from the end of the lower corner area, thereby preventing a path through which external moisture penetrates from occurring.

The organic insulating layer has a broken area in an outer area of the lower corner area adjacent to the bendable area of the substrate, thereby preventing external moisture from penetrating through the organic insulating layer toward the display area.

According to an embodiment of the present disclosure, the barrier structure may be disposed in the outer area of the lower corner area of the display panel to form a structure robust against external moisture penetration.

Accordingly, the external moisture may be prevented from penetrating into the display area through the organic insulating material, thereby preventing the film lift-off.

In addition, the organic insulating material may be prevented from acting as a moisture penetration path, thereby suppressing a defect resulting from damage to the signal line disposed adjacent to the outer area of the lower corner area of the display panel which may otherwise occur due to exposure to the moisture. Accordingly, a signal or voltage for operating the display area may be stably provided, such that product reliability may be improved.

According to the embodiments of the present disclosure, the defect rate of the display device due to the corrosion of the signal line is lowered, so that the production energy required for the production of the display device may be reduced, thereby reducing the emission of greenhouse gas.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a plan view of a display panel according to embodiments of the present disclosure.

FIG. 2 is a cross-sectional view taken along a line II-II′ of FIG. 1.

FIG. 3 is a cross-sectional view taken along a line II-II′ of FIG. 1.

FIGS. 4 and 5 are diagrams according to an embodiment of the present disclosure

FIGS. 6 and 7 are diagrams according to an embodiment of the present disclosure.

### DETAILED DESCRIPTION

Advantages and Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to, or coupled to the other element or layer, or one or more intervening elements or layers may be present therebetween.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

In addition, it will also be understood that when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

The present disclosure focuses on preventing moisture related corrosion and film lift off in the lower corner non display area of a flexible display panel, particularly where the bendable area meets the rigid display area. To address this, the design introduces multiple moisture blocking structures such as barrier structures and dams that are arranged with specific spacing across two functional zones. One zone contains stacked inorganic layers and the other exposes the substrate. One of the features is that the outermost barrier structure is positioned with a deliberate gap from the lower corner end, which removes continuous organic insulating paths that would otherwise allow moisture to migrate toward wiring.

Another aspect is the intentional formation of a broken area in the organic insulating material between certain barrier structures. This interrupts the continuity of organic layers that typically act as moisture penetration pathways, especially after dry etching damage. The barrier structures use carefully selected stacked layers derived from planarization layers and organic insulating layers to cover the ends of inorganic insulating stacks and protect signal lines such as the VSS power line from corrosion.

Together, these structural and material distribution strategies address a reliability problem in flexible and narrow bezel OLED displays. By controlling geometry, material continuity, and protective coverage, the design improves resistance to moisture penetration, prevents film lift off, and enhances overall device durability and production yield.

Hereinafter, a display device according to an embodiment of the present disclosure will be described with reference to the drawings.

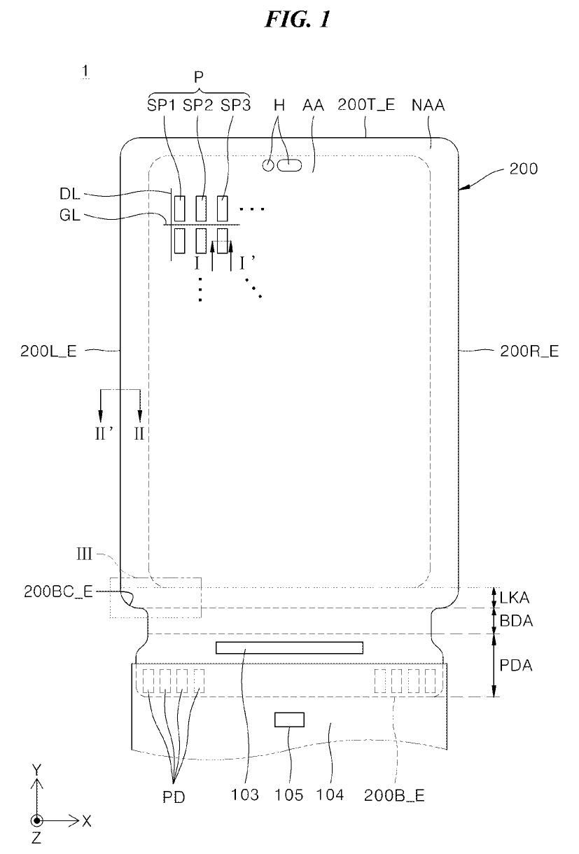

FIG. 1 is a plan view of a display panel according to an embodiment of the present disclosure.

Referring to FIG. 1, a display device 1 according to an embodiment of the present disclosure may include a display panel 200, a printed circuit board 104, a control circuit chip 105, etc.

The display panel 200 may include a display area AA and a non-display area NAA. The display area AA is an area in which an image is displayed, and a plurality of pixels P, data lines DL, and gate lines GL may be disposed in the display area. The non-display area NAA may be an area in which no image is displayed. The non-display area NAA may be located in a peripheral area (or an edge area) of the display panel 200. However, the present disclosure is not limited thereto. For example, an area other than a light emission area in which light is emitted to the outside in the display area AA may be referred to as the non-display area NAA. The bezel area of the display device may be defined by the non-display area NAA. The bezel zone BZA may surround an outside of the display area AA.

The non-display area NAA may include four end portions 200T_E, 200L_E, and 200R_E, 200B_E located as the outermost side of the display panel 200. The outermost end portions 200T_E, 200L_E, 200R_E, and 200B_E may include an upper end portion 200T_E, a left end portion 200L_E, a right end portion 200R_E, and a lower end portion 200B_E. Further, a lower corner end 200BC_E is disposed between each of the left end portion 200L_E and the right end portion 200R_E and the lower end portion 200B_E. A Link area LKA, a bendable area BDA, and a pad area PDA may be disposed between the lower corner end 200BC_E and the lower end portion 200B_E of the display panel 200.

Lines for providing an electrical signal to the display area AA or receiving an electrical signal from the display area AA may be disposed in the non-display area NAA. For example, a gate driver for supplying a gate signal to the plurality of sub-pixels SP1, SP2, and SP3 of the display area AA may be disposed in the non-display area NAA. The gate driver may be disposed at each of right and left edges of the non-display area NAA in a gate in panel (GIP) manner. The gate driver may transmit a gate signal through the gate lines GL.

The non-display area NAA may include a pad area PDA in which a driving circuit chip 103 and a plurality of pads PD are disposed. The driving circuit chip 103 may transmit a data signal to the plurality of sub-pixels SP1, SP2, and SP3 through the plurality of data lines DL in the display area AA. For example, the driving circuit chip 103 may be a data driving circuit chip. However, embodiments of the present disclosure are not limited thereto.

The gate lines GL may extend in the first direction X of the display panel 200, and the data lines DL may intersect the gate lines GL and extend in the second direction Y of the display panel 200.

The non-display area NAA may include the link area LKA. The link area LKA may include data link lines for electrically connecting the plurality of data lines DL of the display area AA to the driving circuit chip 103, or touch link lines for electrically connecting touch lines to the driving circuit chip 103. For example, the link area LKA may be disposed between the display area AA and the pad area PDA, and the bendable area BDA may be disposed between the link area LKA and the pad area PDA.

The bendable area BDA of the display panel 200 may bent to allow a printed circuit board 104 on which a control circuit chip 105 is disposed to face a rear surface of the display area AA of the display panel 200. The control circuit chip 105 may control the driving circuit chip 103 and the gate driver.

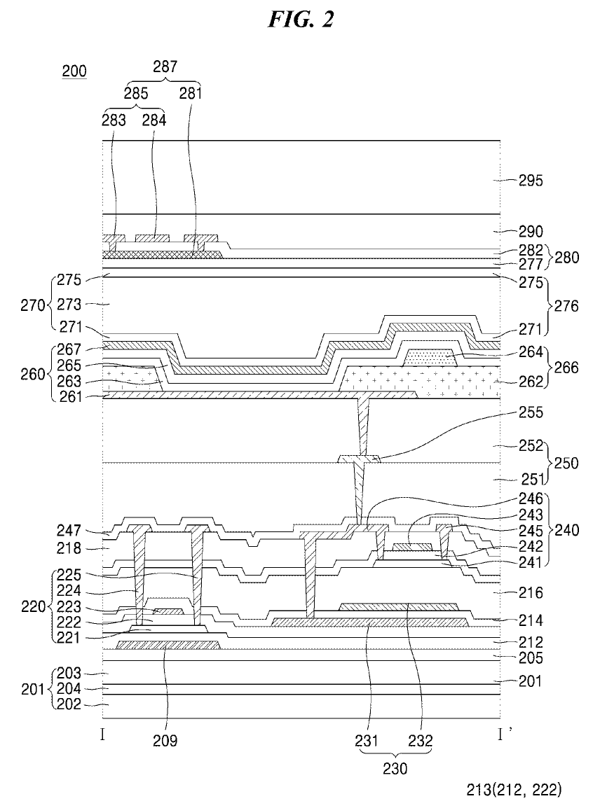

As the bendable area BA of the display panel 200 is bent, the pad area PDA of the non-display area NAA may be located under the display area AA. Accordingly, the lower portion of the non-display area NAA that is visible from the front of the display device 1 may be reduced.. FIG. 2 is a cross-sectional view taken along a line I-I′ of FIG. 1. FIG. 2 schematically illustrates one sub-pixel of a display device. In the present disclosure, for convenience of description, an example of a configuration of one sub-pixel is described. However, the present disclosure is not limited thereto.

The display area AA may include a plurality of pixels P and a hole H. The hole H may be an area in which an electronic component for adding various functions to the display device 1 is disposed. For example, the electronic component may include a camera module for taking a picture or an image, or may include various sensor devices for detecting an external object. The sensor device may include at least one of a proximity sensor, a gesture sensor, a color sensor, a biometric sensor, and an infrared sensor. However, embodiments of the present disclosure are not limited thereto.

One pixel P may include a plurality of sub-pixels SP1, SP2, and SP3. An image may be displayed in the display area AA through the plurality of sub-pixels SP1, SP2, and SP3. The plurality of sub-pixels SP1, SP2, and SP3 may be arranged in an array in the display area AA. In an example, the plurality of sub-pixels SP1, SP2, and SP3 may be arranged in a matrix manner and may be spaced apart from each other in the first direction of the display area AA and the second direction intersecting the first direction. The first direction may be a horizontal direction, an X-axis direction, or a row direction, and the second direction may be a vertical direction, a Y-axis direction, or a column direction. However, the present disclosure is not limited thereto, and the arrangement shape, arrangement order, and arrangement direction of the sub-pixels SP1, SP2, and SP3 may be variously changed.

In the present disclosure, one pixel P is configured to include the first sub-pixel SP1, the second sub-pixel SP2, and the third sub-pixel SP3. However, the present disclosure is not limited thereto. For example, one pixel P may further include an additional sub-pixel.

The sub-pixels SP1, SP2, and SP3 may be implemented to emit light of the same color such as white light. Alternatively, the sub-pixels SP1, SP2, and SP3 may be implemented to emit light of different colors such as red, green, and blue colors. For example, the first sub-pixel SP1 may emit light of red, the second sub-pixel SP2 may emit light of green, and the third sub-pixel SP3 may emit light of blue.

Referring to FIG. 2, the display panel 200 may include a pixel driving circuit including a plurality of transistors 220 and 240 disposed on a substrate 201, a light-emitting element 260, and a touch sensor 287.

One sub-pixel may include a light-emitting element 260 and a pixel driving circuit that applies a driving current to the light-emitting element 260. The pixel driving circuit is disposed on the substrate 201, and the light-emitting element 260 is disposed on the pixel driving circuit. The pixel driving circuit may include a plurality of transistors 220 and 240 and a storage capacitor 230. In an example, the plurality of transistors 220 and 240 may include a first transistor 220 and a second transistor 240.

The substrate 201 may be a flexible plastic substrate. When the substrate 201 is formed as a plastic film, the substrate 201 may include multiple layers made of an insulating material. For example, the substrate 201 may include a first base layer 202, a second base layer 203, and a support layer 204. The first base layer 202 and the second base layer 203 may be disposed to be spaced apart from each other vertically, and the support layer 204 may be disposed therebetween.

Each of the first base layer 202 and the second base layer 203 may include an insulating material having softness. For example, each of the first base layer 202 and the second base layer 203 may include polyimide. The support layer 204 may support the first and second base layers 202 and 203 having relatively softness. The support layer 204 may include an insulating material that is relatively more rigid than the first and second base layers 202 and 203. For example, the support layer 204 may include silicon oxide (SiOx) or silicon nitride (SiNx).

A first buffer layer 205 may be disposed on the substrate 201. The first buffer layer 205 may cover a surface of the substrate 201. The first buffer layer 205 may reduce or prevent penetration of moisture, oxygen, or impurities through the substrate 201. The first buffer layer 205 may be embodied as a single layer or a multilayer made of an inorganic insulating material such as silicon oxide (SiOx) or silicon nitride (SiNx). The first buffer layer 205 may entirely cover the surface of the substrate 201 in the display area AA. For example, the first buffer layer 205 may extend to the non-display area NAA surrounding the outside of the display area AA.

A light-shielding layer 209 may be disposed on the first buffer layer 205. The light-shielding layer 209 may prevent external light from being incident on the transistor TR. To this end, the light-shielding layer 209 may include an opaque metal material. A second buffer layer 212 may be disposed on the light-shielding layer 209. The second buffer layer 212 may protect the transistor TR from moisture, oxygen, or impurities. The second buffer layer 212 may be embodied as a single layer or a multilayer made of an inorganic insulating material such as silicon oxide (SiOx) or silicon nitride (SiNx). However, embodiments of the present disclosure are not limited thereto. The second buffer layer 212 may entirely cover the surface of the substrate 201 in the display area AA. For example, the second buffer layer 212 may extend to the non-display area NAA surrounding the outside of the display area AA.

The first transistor 220 may be disposed on the second buffer layer 212. The first transistor 220 may include a first semiconductor layer 221, a first gate insulating layer 222, a first gate electrode 223, a first source electrode 224, and a first drain electrode 225. In an example, the first transistor 220 may be a switching transistor.

The first semiconductor layer 221 may include a channel area and source/drain areas. An area of the first semiconductor layer 221 overlapping the first gate electrode 223 in the vertical direction may be a channel area. The source/drain areas may be disposed on both opposing sides of the channel area, respectively. The first semiconductor layer 221 may include one of a polysilicon semiconductor layer and a low-temperature polysilicon semiconductor layer, or a combination thereof. In another example, the first semiconductor layer 221 may include an oxide semiconductor layer. For example, the first semiconductor layer 221 may include at least one of an oxide semiconductor material such as IGZO (Indium Gallium Zinc Oxide) or IZO (Indium Zinc Oxide).

When the first semiconductor layer 221 includes the oxide semiconductor layer, the first transistor 220 may be embodied as an oxide thin-film transistor. The first semiconductor layer 221 may be disposed to overlap the light-shielding layer 209 in the vertical direction. The light-shielding layer 209 may prevent external light from being incident on the first semiconductor layer 221.

The first gate insulating layer 222 may be disposed between the first semiconductor layer 221 and the first gate electrode 223. The first gate insulating layer 222 may extend outwardly while covering the first semiconductor layer 221. The first gate insulating layer 222 may be embodied as a single layer or a stack of a plurality of layers made of an inorganic insulating material such as silicon oxide (SiOx) or silicon nitride (SiNx). The first gate insulating layer 222 may entirely cover the surface of the substrate 201 in the display area AA. For example, the first gate insulating layer 222 may extend to the non-display area NAA surrounding the outside of the display area AA. In the non-display area NAA, the second buffer layer 212 and the first gate insulating layer 222 may be arranged in the vertical direction so as to be in contact with each other to constitute a first insulating structure 213.

The first gate electrode 223 may be disposed on the first gate insulating layer 222. A first interlayer insulating layer 214 may be disposed on the first gate electrode 223. The first interlayer insulating layer 214 may be embodied as a single layer or a stack of multiple layers made of an inorganic insulating material such as silicon oxide (SiOx) or silicon nitride (SiNx). In an example, the first interlayer insulating layer 214 may extend to the non-display area NAA surrounding the outside of the display area AA.

The first source electrode 224 and the first drain electrode 225 may be electrically connected to the first semiconductor layer 221.

The storage capacitor 230 may include a first storage electrode 231 and a second storage electrode 232. For example, the first storage electrode 231 and the first gate electrode 223 may be formed on the same layer 222. For example, the first storage electrode 231 may be disposed on the first gate insulating layer 222 and at a position horizontally spaced apart from the first gate electrode 223. The first storage electrode 231 may be made of the same material as that of the first gate electrode 223. The second storage electrode 232 may be disposed on the first interlayer insulating layer 214 so as to overlap the first storage electrode 231 in the vertical direction.

Each of the first storage electrode 231 and the second storage electrode 232 may be embodied as a single layer or as a stack of multiple layers made of one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto. The second transistor 240 may be disposed on the second interlayer insulating layer 216 so as to be spaced apart from the first transistor 220. The second transistor 240 may be electrically connected to the first transistor 220. For example, the second transistor 240 may include a second semiconductor layer 241, a second gate insulating layer 242, a second gate electrode 243, a second source electrode 245, and a second drain electrode 246. In an example, the second transistor 240 may be a driving transistor electrically connected to the light-emitting element 260.

A second interlayer insulating layer 216 may be disposed on the second storage electrode 232. The second interlayer insulating layer 216 may be embodied as a single layer or a stack of multiple layers made of an inorganic insulating material such as silicon oxide (SiOx) or silicon nitride (SiNx). In an example, the second interlayer insulating layer 216 may extend to the non-display area NAA surrounding the outside of the display area AA.

The second semiconductor layer 241 may include a channel area and source/drain areas. A area of the second semiconductor layer 241 overlapping the second gate electrode 243 in the vertical direction may be a channel area. The source/drain areas may be disposed on both opposing sides of the channel area, respectively. The second semiconductor layer 241 may include an oxide semiconductor layer. For example, the second semiconductor layer 241 may include at least one of an oxide semiconductor material such as indium gallium zinc oxide (IGZO) or indium zinc oxide (IZO). In an example, the second semiconductor layer 241 may be disposed to overlap the storage capacitor 230 in the vertical direction. Accordingly, the storage capacitor 230 may prevent the external light from the outside out of the substrate 201 from being incident on the second semiconductor layer 241. Accordingly, this may prevent the characteristics of the second transistor 240 from being changed by the external light.

The second gate insulating layer 242 may be disposed between the second semiconductor layer 241 and the second gate electrode 243. The second gate insulating layer 242 may extend outwardly while covering the second semiconductor layer 241. For example, the second gate insulating layer 242 may extend to the non-display area NAA surrounding the outside of the display area AA. The second gate insulating layer 242 may be embodied as a single layer or a stack of a plurality of layers made of an inorganic insulating material such as silicon oxide (SiOx) or silicon nitride (SiNx).

Each of the first gate electrode 223 or the second gate electrode 243 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, an example of the material is not limited thereto.

A third interlayer insulating layer 218 may be disposed on the second gate electrode 243. The third interlayer insulating layer 218 may include an insulating material. For example, the third interlayer insulating layer 218 may include an inorganic insulating material such as silicon oxide (Six), silicon nitride (SiNx), or silicon oxynitride (SiON), and may be embodied as a single layer or a stack of multiple layers. In an example, the third interlayer insulating layer 218 may extend to the non-display area NAA surrounding the outside of the display area AA.

The first source electrode 224, the first drain electrode 225, the second source electrode 245, and the second drain electrode 246 may be disposed on the third interlayer insulating layer 218.

The first source electrode 224 and the first drain electrode 225 may extend through the third interlayer insulating layer 218, the second gate insulating layer 242, the second interlayer insulating layer 216, the first interlayer insulating layer 214, and the first gate insulating layer 222 so as to be in direct contact with and be electrically connected to the source/drain areas of the first semiconductor layer 221, respectively.

The second source electrode 245 and the second drain electrode 246 may extend through the third interlayer insulating layer 218 and the second gate insulating layer 242 so as to directly contact and be electrically connected to the source/drain areas of the second semiconductor layer 241, respectively. The second drain electrode 246 of the second transistor 240 may be electrically connected to the storage capacitor 230. For example, a portion of the second drain electrode 246 may extend through the third interlayer insulating layer 218, the second gate insulating layer 242, the second interlayer insulating layer 216, and the first interlayer insulating layer 214 so as to be in direct contact with and be electrically connected to the first storage electrode 231 of the storage capacitor 230.

Each of the first source electrode 224, the first drain electrode 225, the second source electrode 245, or the second drain electrode 246 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. In an example, each of the first source electrode 224 or the second drain electrode 225 may have a stack structure of titanium layer/aluminum layer/titanium layer (Ti/Al/Ti).

A passivation layer 247 may be disposed on the first source electrode 224, the first drain electrode 225, the second source electrode 245, or the second drain electrode 246. The passivation layer 247 may include an inorganic insulating material such as silicon oxide, silicon nitride, and silicon oxynitride, and may be embodied as a single layer or a stack of multiple layers. The passivation layer 247 may protect the pixel driving circuit disposed thereunder.

A planarization layer 250 may be disposed on the passivation layer 247. The planarization layer 250 may planarize a step caused due to the pixel driving circuit thereunder. The planarization layer 250 may include a multilayer structure of a first planarization layer 251 and a second planarization layer 252. For example, the planarization layer 250 may include an organic insulating material such as polyimide or acrylic resin. In an example, each of the first planarization layer 251 and the second planarization layer 252 may extend to the non-display area NAA surrounding the outside of the display area AA.

A pixel contact electrode 255 may be disposed on the first planarization layer 251. The pixel contact electrode 255 may extend thorough the first planarization layer 251 and the passivation layer 247 so as to directly contact the first drain electrode 246 of the second transistor 240.

The light-emitting element 260 may be formed on the planarization layer 250. For example, the light-emitting element 260 may be disposed on the second planarization layer 252. The light-emitting element 260 may include a first electrode 261, a light-emitting layer 263, a second electrode 265, and a capping layer 267.

The light-emitting element 260 may be electrically connected to the pixel driving circuit via the first electrode 261. For example, the first electrode 261 may extend through the second planarization layer 252 so as to directly contact the pixel contact electrode 255. Accordingly, the first electrode 261 may be electrically connected to the second transistor 240 via the pixel contact electrode 255. However, FIG. 2 is indented for illustrating an example of a scheme of supplying a current to the first electrode 261, and the present disclosure is not limited to physical contact between the second transistor 240 as the driving transistor and the first electrode 261. In an example, the switching transistor ST electrically connected to the first electrode 261 may be a light-emission transistor. For example, the light-emission transistor may control the turn-on and turn-off states of the light-emitting element 260. The pixel contact electrode 255 may include a conductive material. For example, the pixel contact electrode 255 may include a metal material such as aluminum (Al), chromium (Cr), copper (Cu), titanium (Ti), molybdenum (Mo), and tungsten (W). In an example, the pixel contact electrode 255 may have a multilayer structure of titanium layer/aluminum layer/titanium layer (Ti/Al/Ti).

The first electrode 261 may include a transparent conductive layer. For example, the first electrode 261 may include ITO (Indium Tin Oxide) or IZO (Indium Zinc Oxide). Alternatively, the first electrode 261 may have a single-layer or a multi-layer structure including a reflective metal film made of one of silver (Ag), aluminum (Al), gold (Au), nickel (Ni), and chromium (Cr) or an alloy thereof. The first electrode 261 may also be referred to as a pixel electrode or an anode electrode.

A bank 262 may be disposed on the first electrode 261. The bank 262 may be disposed to cover an edge of the first electrode 261. A portion of the bank 262 may extend to the second planarization layer 252. A portion of an upper surface of the first electrode 261 not covered with the bank 262 so as to be exposed may be the light emission area EA. The bank 262 may be made of an organic insulating material. The bank 262 may include, for example, photosensitive polyimide, photoacryl, or benzocyclobutene (BCB).

A spacer 264 may be further disposed on the bank 262. The spacer 264 may be disposed to prevent damage to the bank 262 and the first electrode 261 during the process. The spacer 264 may be made of the same material as that of the bank 262. The bank 262 and the spacer 264 may be stacked vertically to constitute an organic insulating structure 266.

The light-emitting layer 263 may be disposed on the first electrode 261. The light-emitting layer 263 may include a hole transport layer HTL, an organic light-emitting layer EML, an electron transport layer ETL, a hole blocking layer HBL, a hole injecting layer HIL, an electron blocking layer EBL, and an electron injecting layer EIL. The light light-emitting layer 263 may have a multi-stack structure in which two or more organic emission layers EML are stacked.

The second electrode 265 may be disposed on the light-emitting layer 263. The second electrode 265 may be commonly connected to the light-emitting layer 263 formed in all pixels. Therefore, the second electrode 265 may also be referred to as a common electrode or a cathode electrode. The second electrode 265 may include a transflective conductive material. For example, the cathode electrode may be made of a metal material such as magnesium (Mg), silver (Ag), or an alloy (Ag-Mg) of silver (Ag) and magnesium (Mg). In an example, the second electrode 265 may include a transparent conductive layer such as indium-tin-oxide (ITO) or indium-zinc-oxide (IZO).

The capping layer 267 may be disposed on the second electrode 265. The capping layer 267 may prevent light generated from the light-emitting layer 263 from being lost, thereby improving light extraction efficiency.

The encapsulation stack 270 may be disposed on the light-emitting element 260. The encapsulation stack 270 may protect the light-emitting element 260 from external oxygen or moisture. The encapsulation stack 270 may extend to the non-display area NAA outside the display area AA while covering the display area AA.

The encapsulation stack 270 may include a multilayer structure in which a first encapsulation layer 271, a second encapsulation layer 273, and a third encapsulation layer 275 are stacked. The second encapsulation layer 273 may be disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may cover the first encapsulation layer 271 and may have a sufficient thickness so as to have a flat upper surface. The second encapsulation layer 273 may prevent foreign substances from penetrating into the light-emitting element 260. The third encapsulation layer 275 may be disposed on the second encapsulation layer 273. Each of the first encapsulation layer 271 and the third encapsulation layer 275 may extend to the non-display area NAA surrounding the outside of the display area AA. The first encapsulation layer 271 and the third encapsulation layer 275 extending to the non-display area NAA may be vertically stacked to constitute an inorganic insulating structure 276.

Each of the first encapsulation layer 271 and the third encapsulation layer 275 may include an inorganic insulating material, and the second encapsulation layer 273 may include an organic insulating material. For example, each of the first encapsulation layer 271 and the third encapsulation layer 275 may include at least one of silicon nitride (SiNx), silicon oxide (SiOx), or silicon oxynitride (SiON). The second encapsulation layer 273 may include at least one of epoxy, polyimide, polyethylene, and acrylate.

A touch area may be disposed on the encapsulation stack 270. The touch area may include a touch buffer layer 277, a touch sensor 287, a touch interlayer insulating layer 282, a first touch protective layer 290, and a second touch protective layer 295.

The touch buffer layer 277 may be disposed on the third encapsulation layer 275. The touch buffer layer 277 may reduce stress between the encapsulation stack 270 and the layer of the touch sensor 287 to prevent the encapsulation stack 270 and the light-emitting element 260 from being damaged. The touch buffer layer 277 may include an inorganic insulating material. For example, the touch buffer layer 277 may include silicon nitride (SiNx).

The touch sensor 287 may include a plurality of touch electrodes 285 and a bridge electrode 281. The plurality of touch electrodes 285 and the bridge electrode 281 may be disposed in different layers. For example, the bridge electrode 281 may be disposed on the touch buffer layer 277. The plurality of touch electrodes 287 may be disposed on the touch interlayer insulating layer 282. The plurality of touch electrodes 287 may include a first touch electrode 283 and a second touch electrode 284. The bridge electrode 281 may electrically connect adjacent first touch electrodes 283 to each other. To this end, the first touch electrode 283 may extend through the touch interlayer insulating layer 282 so as to be connected to the bridge electrode 281. The touch interlayer insulating layer 282 may include an inorganic insulating material. For example, the touch interlayer insulating layer 282 may include silicon nitride (SiNx).

The first touch electrode 283, the second touch electrode 284, or the bridge electrode 281 may include a conductive material. The first touch electrode 283, the second touch electrode 284, or the bridge electrode 281 may include a single layer or a stack of multiple layers made of one of molybdenum (Mo), aluminum (Al), chromium (Cr), gold (Au), titanium (Ti), nickel (Ni), neodymium (Nd), and copper (Cu) or an alloy thereof.

Each of the touch buffer layer 277 and the touch interlayer insulating layer 282 may extend toward the non-display area NAA. The touch buffer layer 277 and the touch interlayer insulating layer 282 may be vertically stacked so as to be in contact with each other in the non-display area NAA to constitute a touch insulating structure 280.

The first touch protective layer 290 may be disposed on the touch sensor 287. The first touch protective layer 290 may prevent damage to the touch sensor 287 from external impact and moisture. The first touch protective layer 290 may include an organic insulating material. For example, the first touch protective layer 290 may be made of a photosensitive acrylic-based or polyimide-based organic material. The first touch protective layer 290 may extend to the non-display area NAA. For example, the first touch protective layer 290 may extend to the non-display area NAA surrounding the outside of the display area AA.

The second touch protective layer 295 may be disposed on the first touch protective layer 290. The second touch protective layer 295 may further protect the touch sensor 287 from external impact and moisture. In addition, the second touch protective layer 295 may planarize a step caused by patterns constituting the touch sensor 287 disposed thereunder. The second touch protective layer 295 may include an organic insulating material. For example, the second touch protective layer 295 may include the same organic insulating material as that of the first touch protective layer 290. However, embodiments of the present disclosure are not limited thereto. For example, the second touch protective layer 295 may include an organic insulating material different from that of the first touch protective layer 295.

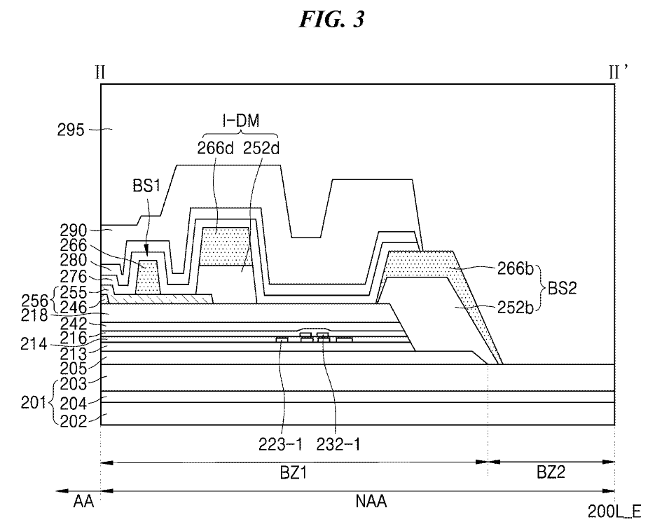

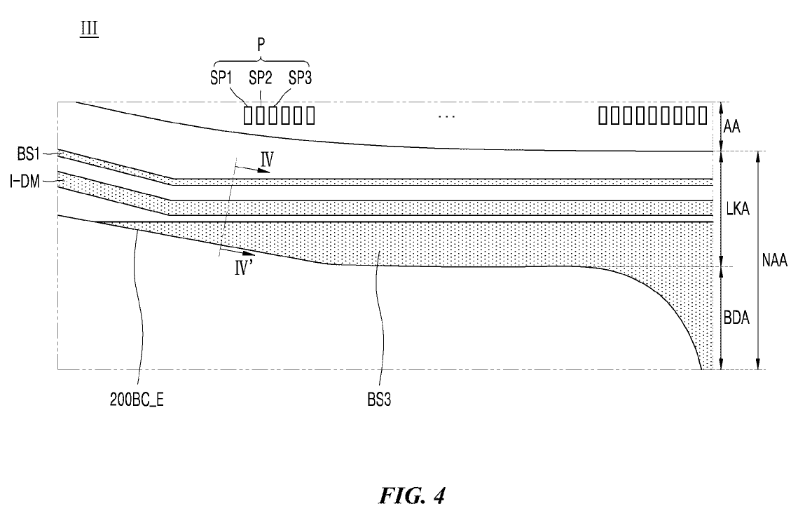

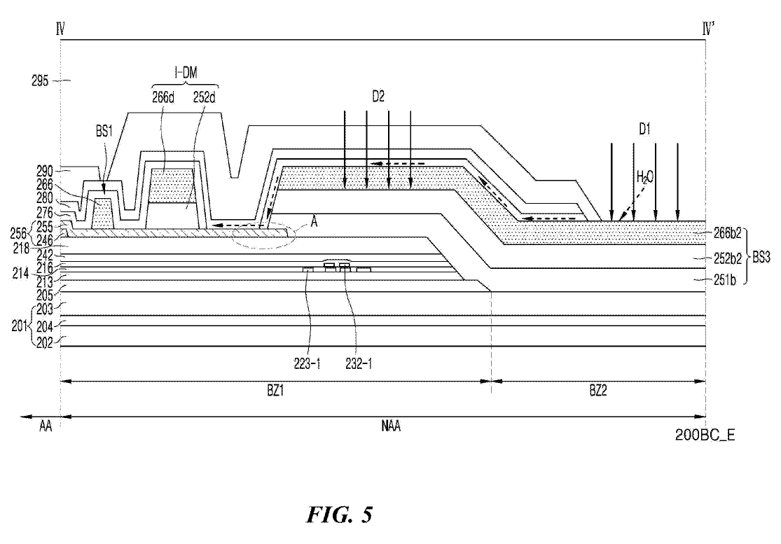

FIG. 3 is a cross-sectional view taken along a line II-II′ of FIG. 1. FIGS. 4 and 5 are diagrams according to an embodiment of the present disclosure. FIG. 4 is an enlarged plan view of an area III of FIG. 1. FIG. 5 is a cross-sectional view taken along a line IV-IV′ of FIG. 4. In FIGS. 4 and 5, descriptions of the same components as those of FIG. 3 will be briefly made or omitted. The same constituent elements may employ the same reference numerals.

FIG. 3 illustrates an example of the left end portion 200L_E among the end portions positioned at the outermost portion of the display panel 200 (see FIG. 1) for convenience of illustration. However, the present disclosure is not limited thereto. For example, each of the upper end portion 200T_E and the right end portion 200R_E may also be configured in the same manner as the confirmation in FIG. 3. FIG. 4 is an enlarged plan view illustrating a partial area of the lower corner end 200BC_E of the lower corner area of the display panel 200 (see FIG. 1). FIG. 4 illustrates an example of a right corner area of the display panel 200 for convenience of illustration. However, embodiments of the present disclosure are not limited thereto. For example, the left corner area of the display panel 200 may also be configured in the same manner as the configuration in FIG. 4.

Referring to FIGS. 1 to 3, the display panel 200 may include the non-display area NAA having the upper side area, the left side area, and the right side area corresponding to an upper side, a left side, and a right side of the display area AA. The non-display area NAA surrounds the outside of the display area AA. Each of the upper side area, the left side area, and the right side area of the non-display area NAA respectively disposed on the upper side, the left side, and the right side of the display area AA may include a first zone BZ1 and a second zone BZ2. The first zone BZ1 may be closer to the display area AA than the second zone BZ2 may be. The first zone BZ1 may be an area in which an end of the first buffer layer 205 having the longest extension length among the inorganic insulating material layers 205, 213, 214, 216, 242, and 218 extending from the display area AA is disposed. A plurality of structures BS1, I-DM, and BS2 may be disposed in the non-display area NAA.

The second zone BZ2 may be an area around the first zone BZ1. The second zone BZ2 may surround the first zone BZ1 and may be an area in which an inorganic insulating material is not disposed. The second zone BZ2 may include the left end portion 200L_E. The second zone BZ2 may include an area in which a surface of the substrate 201 is exposed. For example, a surface of the second base layer 203 of the substrate 201 may be exposed. For example, a portion of the second zone BZ2 disposed on the upper side of the display area AA may include the upper end portion 200 T_E. For example, a portion of the second zone BZ2 disposed on the right side of the display area AA may include the right end portion 200 R_E.

The plurality of structures BS1, I-DM, and BS2 may include a second barrier structure BS2 farthest from the display area AA, a first barrier structure BS1 closest to the display area, and an inner dam I-DM disposed between the first barrier structure BS1 and the second barrier structure BS2. The second barrier structure BS2, the inner dam I-DM, and the first barrier structure BS1 are spaced from each other. The first barrier structure BS1 and the inner dam I-DM may be disposed in the first zone BZ1, while the second barrier structure BS2 may be disposed to overlap a boundary area of the first zone BZ1 and the second zone BZ2.

The inorganic insulating material layers 205, 213, 214, 216, 242, and 218 extending from the display area AA may be vertically stacked on the substrate 201 in the first zone BZ1. Accordingly, the inorganic insulating material layers 205, 213, 214, 216, 242, and 218 may constitute a stack of multiple layers. For example, the stack of the inorganic insulating material layers 205, 213, 214, 216, 242, and 218 may include a stack structure in which the first buffer layer 205, the first insulating structure 213, the first interlayer insulating layer 214, the second interlayer insulating layer 216, the second gate insulating layer 242, and the third interlayer insulating layer 218 are vertically stacked. For example, the first buffer layer 205 contacting the second base layer 203 of the substrate 201 among the inorganic insulating material layers 205, 213, 214, 216, 242, and 218 may further extend toward the second zone BZ2 beyond each of the other inorganic insulating material layers 213, 214, 216, 242, and 218.

The inorganic insulating material layers 205, 213, 214, 216, 242, and 218 may extend to and along the first zone BZ1 such that ends thereof may be disposed in the first zone BZ1. For example, among the inorganic insulating material layers 205, 213, 214, 216, 242, and 218, the other inorganic insulating material layers 213, 214, 216, 242, and 218, excluding the first buffer layer 205, may be aligned such that their end portions form an inclined surface. The first buffer layer 205 may further extend beyond each of the other inorganic insulating material layers 213, 214, 216, 242, and 218 toward the second zone BZ2 such that an end portion of the first buffer layer 205 may be positioned so as to vertically overlap at a boundary area between the first zone BZ1 and the second zone BZ2.

First conductive patterns 223-1 may be disposed on the first insulating structure 213 so as to be spaced apart from each other. The first conductive patterns 223-1 may be made of the same material as that of and may be formed in the same process as that of the first gate electrode 223. The first conductive patterns 223-1 may be covered with the first interlayer insulating layer 214. Second conductive patterns 232-1 may be disposed on the first interlayer insulating layer 214 so as to be spaced apart from each other. The second conductive patterns 232-1 may be made of the same material as that of and may be formed in the same process as that of the second storage electrode 232. However, embodiments of the present disclosure are not limited thereto. The second conductive patterns 232-1 may be covered with the second interlayer insulating layer 216. The first conductive pattern 223-1 and the second conductive pattern 232-1 may be disposed to overlap each other vertically. The first conductive pattern 223-1 and the second conductive pattern 232-1 may be disposed in an area between the inner dam I-DM and the second barrier structure BS2 in the plan view of the display device.

For example, the first conductive patterns 223-1 or the second conductive pattern 232-1 may be conductive lines that transmit signals or voltages to the pixel driving circuit disposed in the display area AA. However, embodiments of the present disclosure are not limited thereto.

A signal line 256 may be disposed on the third interlayer insulating layer 218 disposed at the uppermost level among the inorganic insulating material layers 205, 213, 214, 216, 242, and 218. The signal line 256 may have a multilayer structure including a first layer made of the same material as that of the second drain electrode 246 and a second layer made of the same material of the pixel contact electrode 255. For example, the signal line 256 may include a low potential power (VSS) line. The low-potential power (VSS) line may provide a reference voltage to the light emitting element 260 disposed in the display area AA. The low-potential power (VSS) line may be disposed to surround the display area AA to lower resistance.

The first barrier structure BS1 disposed at a position closest to the display area AA and in the first zone BZ1 may include the organic insulating structure 266. The organic insulating structure 266 may be formed in the process of forming the bank 262 and the spacer 264 of the display area AA. Accordingly, the organic insulating structure 266 may be made of the same material as the bank 262 and the spacer 264. In an example, the first barrier structure BS1 may be disposed on the signal line 256.

The inner dam I-DM may be spaced apart from the first barrier structure BS1 and may be disposed in the first zone BZ1. The inner dam I-DM may have a structure in which a (1-1)st layer 252d and a (2-1)st layer 266d are vertically stacked. For example, the (1-1)st layer 252d may be made of the same material as that of and may be formed in the same process as that of the second planarization layer 252. The (2-1)st layer 266d may be made of the same material as that of and be formed in the same process as that of the organic insulating structure 266. A partial area of the (1-1)st layer 252d may be disposed to vertically overlap the signal line 256 and to cover an end of the signal line 256.

The second barrier structure BS2 may be disposed to vertically overlap the boundary area between the first zone BZ1 and the second zone BZ2. The second barrier structure BS2 may have a structure in which a (1-2)nd layer 252b and a (2-2)nd layer 266b are vertically stacked. For example, the (1-2)nd layer 252b may be made of the same material as that of and be formed in the same process as that of the second planarization layer 252. The (2-2)nd layer 266b may be made of the same material as that of and be formed in the same process as that of the organic insulating structure 266. A partial area of the (1-2)nd layer 252b may cover an end portion of each of the inorganic insulating material layers 205, 213, 214, 216, 242, and 218. The (2-2)nd layer 266b may be disposed to cover an upper surface and a side surface of the (1-2)nd layer 252b.

The inorganic insulating structure 276 and the touch insulating structure 280 may be vertically stacked on the first barrier structure BS1, the inner dam I-DM, and the second barrier structure BS2. The inorganic insulating structure 276 and the touch insulating structure 280 may extend from the display area AA onto and along a partial area of the first zone BZ1 of the non-display area NAA. For example, each of the inorganic insulating structure 276 and the touch insulating structure 280 may cover both the first barrier structure BS1 and the inner dam I-DM. Each of the inorganic insulating structure 276 and the touch insulating structure 280 may cover only a partial area of the second barrier structure BS2. For example, a portion of an upper surface and an inclined side surface of the (2-2)nd layer 266b1 of the second barrier structure BS2 in an area adjacent to the second zone BZ2 may not be covered with the inorganic insulating structure 276 and the touch insulating structure 280. The portion of the upper surface and the inclined surface of the (2-2)nd layer 266b of the second barrier structure BS2 may be exposed by forming the inorganic insulating structure 276 and then performing a dry etching process on the inorganic insulating structure 276.

The inorganic insulating structure 276 and the touch insulating structure 280 may be covered with the first touch protective layer 290. For example, an end portion of each of the inorganic insulating structure 276 and the touch insulating structure 280 disposed in an edge area of the first zone BZ1 may be covered with the first touch protective layer 290.

The second touch protective layer 295 may be disposed on the first touch protective layer 290. The second touch protective layer 295 may cover the first touch protective layer 290 and the exposed portion of the upper surface and the exposed inclined surface of the (2-2)nd layer 266b of the second barrier structure BS2. Each of the first touch protective layer 290 and the second touch protective layer 295 may include an organic insulating material.

The non-display area NAA surrounding the outside of the display area AA of the display panel 200 may include the end portions 200T_E, 200L_E, 200R_E, and 200B_E, and the lower corner end 200BC_E. In a portion of the non-display area NAA including the upper end portion 200T_E, the left end portion 200L_E, and the right end portion 200R_E, the end portion of each of the inorganic insulating material layers 205, 213, 214, 216, 242, and 218 may be covered with a portion of the second barrier structure BS2 including an organic insulating material. The portion of the second barrier structure BS2 including the organic insulating material may be disposed in the first zone BZ1 of the non-display area NAA and may not be disposed in the second zone BZ2 thereof.

In addition, an end portion of the signal line 256 may be covered with the inner dam I-DM disposed inwardly of the second barrier structure BS2. The inner dam I-DM may be covered with the inorganic insulating structure 276 including the inorganic insulating material and the touch insulating structure 280.

Accordingly, the organic insulating material of the portion of the non-display area NAA including the upper end portion 200T_E, the left end portion 200L_E, and the right end portion 200R_E may not be damaged even when the inorganic insulating structure 276 is formed and the dry etching process is performed thereon. Accordingly, the signal line 256 disposed on the portion of the non-display area NAA including the upper end portion 200T_E, the left end portion 200L_E, and the right end portion 200R_E may be prevented from corrosion due to moisture penetration.

In a portion of the non-display area NAA including the lower corner end 200BC_E of the lower corner area of the non-display area NAA, an organic insulating material layer may continuously extend from the display area AA to the lower corner end 200BC_E. The organic insulating material layer may continuously extend onto and along the lower corner area including the lower corner end 200BC_E and the bendable area BDA to protect the lines disposed therein from foreign substances. However, when the organic insulating material layer extends onto and along the lower corner area including the lower corner end 200BC_E of the display panel, the organic insulating material layer may be damaged in the process of forming the inorganic insulating structure 276 and performing the dry etching process thereon, such that the damage point acts as a point where moisture invasion occurs.

Hereinafter, the present disclosure will be described with reference to FIGS. 4 and 5.

Referring to FIGS. 1, 4, and 5, the portion of the non-display area NAA disposed in the lower corner area of the display panel 200 may include the first zone BZ1 and the second zone BZ2. The lower corner area of the display panel 200 may be connected to the bendable area BDA. The first zone BZ1 may be an area in which an end of the first buffer layer 205 having the longest extension length among the inorganic insulating material layers 205, 213, 214, 216, 242, and 218 extending from the display area AA is disposed. The first barrier structure BS1 and the inner dam I-DM may be disposed in the first zone BZ1 of the non-display area NAA.

The second zone BZ2 may be an area disposed outwardly of the first zone BZ1. The second zone BZ2 may surround the first zone BZ1 and may be an area in which the inorganic insulating material is not disposed. The second zone BZ2 may include the lower corner end 200BC_E of the lower corner area of the non-display area NAA.

The inorganic insulating material layers 205, 213, 214, 216, 242, and 218 extending from the display area AA may be vertically stacked on the substrate 201 in the first zone BZ1. The signal line 256 may be disposed on the third interlayer insulating layer 218 disposed at the uppermost level among the inorganic insulating material layers 205, 213, 214, 216, 242, and 218. The signal line 256 may have a multilayer structure including the first layer made of the same material as that of the second drain electrode 246 and the second layer made of the same material as that of the pixel contact electrode 255 of the pixel driving circuit disposed in the display area AA. For example, the signal line 256 may include the low potential power (VSS) line.

The first barrier structure BS1 and the inner dam I-DM may be disposed on the signal line 256. The first barrier structure BS1 may include the organic insulating structure 266. The inner dam I-DM may be spaced apart from the first barrier structure BS1 and may be disposed in the first zone BZ1. The inner dam I-DM may have a structure in which the (1-1)st layer 252d and the (2-1)st layer 266d are vertically stacked. For example, the (1-1)st layer 252d may be made of the same material as that of and be formed in the same process as that of the second planarization layer 252. The (2-1)st layer 266d may be made of the same material as that of and be formed in the same process as that of the organic insulating structure 266. A partial area of the (1-1)st layer 252d may be disposed to vertically overlap the signal line 256 and to cover the end portion of the signal line 256.

A third barrier structure BS3 may be spaced apart from the inner dam I-DM and may be closer to the lower corner end 200BC_E than the inner dam I-DM may be. The third barrier structure BS3 may be disposed to continuously extend on and along the lower corner area including the lower corner end 200BC_E of the display panel 200 and the bendable area BDA of the display panel 200.

The third barrier structure BS3 may have a structure in which a (1-1)st layer 251b as a lower layer, a (1-3)rd layer 252b2 as a middle layer, and a (2-3)rd layer 266b2 as an upper layer are vertically stacked. For example, the (1-1)st layer 251b may be made of the same material as that of and be formed in the same process as that of the first planarization layer 251. The (1-3)rd layer 252b2 may be made of the same material as that of and be formed in the same process as that of the second planarization layer 252. The (2-3)rd layer 266b2 may be made of the same material as that of and be formed in the same process as that of the organic insulating structure 266.

One side area of the third barrier structure BS3 may cover the end portion of the signal line 256. The third barrier structure BS3 may extend toward the lower corner end 200BC_E of the lower corner area of the display panel so as to cover the end portion of each of the inorganic insulating material layers 205, 213, 214, 216, 242, and 218 and may extend to the lower corner end 200BC_E of the lower corner area of the display panel.

The inorganic insulating structure 276 and the touch insulating structure 280 may be vertically stacked on the first barrier structure BS1, the inner dam I-DM, and the third barrier structure BS3. The inorganic insulating structure 276 and the touch insulating structure 280 may be covered with the first touch protective layer 290. For example, the end portion of each of the inorganic insulating structure 276 and the touch insulating structure 280 disposed in the second zone BZ2 may be covered with the first touch protective layer 290. The second touch protective layer 295 may be disposed on the first touch protective layer 290. The second touch protective layer 295 may cover the first touch protective layer 290 and the exposed portion of the upper surface of the (2-3)rd layer 266b2 the third barrier structure BS3. Each of the first touch protective layer 290 and the second touch protective layer 295 may include an organic insulating material.

When the inorganic insulating structure 276 is formed and a dry etching process is performed thereon in a state in which the third barrier structure BS3 including the organic insulating material layers has been disposed, damage D1 and D2 may occur onto the (2-3)rd layer 266b2 as the uppermost layer. The moisture (H₂O) may penetrate into the damaged portion of the (2-3)rd layer 266b2 including the organic insulating material. The organic insulating material may act as a movement path of moisture (H₂O).

The third barrier structure BS3 including the (2-3)rd layer 266b2 may extend from the second zone BZ1 onto and along a portion of the first zone BZ1 of the non-display area NAA and may cover the end portion of the signal line 256. Accordingly, the moisture (H₂O) permeated through the (2-3)rd layer 266b2 may flow to an area ‘A’ as indicated by a dotted arrow in FIG. 5. The moisture having flowed to the area ‘A’ may be in contact with the signal line 256. When a voltage is applied in a state in which the signal line 256 is in contact with moisture and invades into the signal line, the corrosion may occur in the signal line 256 due to an electric field and the moisture. The corrosion of the signal line 256 may result in a defect of the display device, thereby causing the product defect.

In addition, in the area ‘A’, a film lift-off may occur in an area between the signal line 256 and the (1-1)-st layer 251b covering the end side of the signal line 256 and including the organic insulating material.

Accordingly, in another embodiment of the present disclosure, a structure capable of preventing the occurrence of the moisture penetration causing defect and the film lift-off defect in the portion of the non-display area NAA including the lower corner end 200BC_E of the lower corner area of the display panel 200 may be proposed.

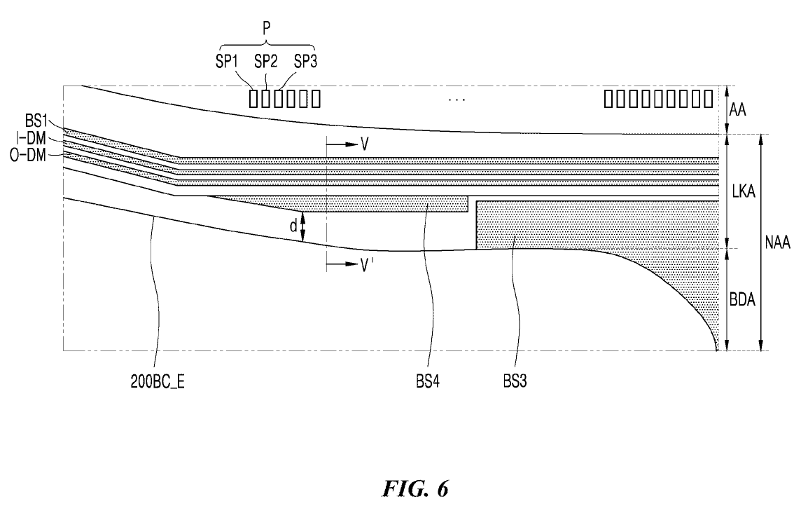

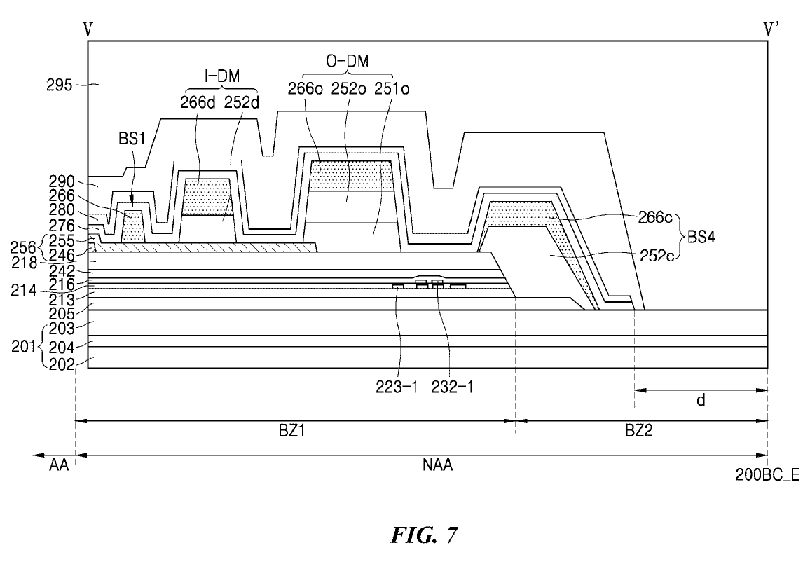

FIGS. 6 and 7 are diagrams according to another embodiment of the present disclosure. FIG. 6 is an enlarged plan view of the area III of FIG. 1. FIG. 7 is a cross-sectional view taken along a line V-V′ of FIG. 6. In FIGS. 6 and 7, descriptions of the same components as those of FIGS. 4 and 5 will be briefly made or omitted. The same constituent elements may employ the same reference numerals.

Referring to FIGS. 6 and 7, the portion of the non-display area NAA disposed in the lower corner area of the display panel 200 may include the first zone BZ1 and the second zone BZ2. The lower corner area of the display panel 200 may be an edge area connected to the bendable area BDA.

The first zone BZ1 may be an area in which the end portion of the first buffer layer 205 having the longest extension length among the multiple inorganic insulating material layers 205, 213, 214, 216, 242, and 218 extending from the display area AA is disposed. The first barrier structure BS1, the inner dam I-DM, and an outer dam O-DM may be disposed in the first zone BZ1 of the non-display area NAA. A fourth barrier structure BS4 may be disposed in the second zone BZ2 and may vertically overlap the boundary between the first zone BZ1 and the second zone BZ2 of the non-display area NAA. The second zone BZ2 may be located outwardly of the first zone BZ1 and may include an area d in which an inorganic insulating material is not disposed. The surface of the substrate 201 may be exposed in the area d in which the inorganic insulating material is not disposed. For example, the area d in which the inorganic insulating material is not disposed may be an area in which the second base layer 203 of the substrate 201 is exposed.

The second zone BZ2 may include the lower corner end 200BC_E of the lower corner area of the display panel 200. As illustrated in FIG. 6, the third barrier structure BS3 including the organic insulating material may be disposed in the portion of the link area LKA and the bendable area BDA of the display panel DP.

The inner dam I-DM and the outer dam O-DM may be disposed in the first zone BZ1 of the non-display area NAA and may be spaced from each other by a predetermined space. The inner dam I-DM may be positioned inwardly of the outer dam O-DM and may be spaced from the first barrier structure BS1 disposed at a position closest to the display area AA.

The inorganic insulating material layers 205, 213, 214, 216, 242, and 218 extending from the display area AA may be vertically stacked on the substrate 201 in the first zone BZ1. The signal line 256 may be disposed on the third interlayer insulating layer 218 among the inorganic insulating material layers 205, 213, 214, 216, 242, and 218. For example, the signal line 256 may include the low potential power (VSS) line.

The first barrier structure BS1 and the inner dam I-DM may be disposed on the signal line 256. The first barrier structure BS1 may include the organic insulating structure 266. The inner dam I-DM may have a structure in which the (1-1)st layer 252d and the (2-1)st layer 266d each including an organic insulating material are vertically stacked.

The fourth barrier structure BS4 may vertically overlap the boundary area between the first zone BZ1 and the second zone BZ2. The third barrier structure BS3 may be disposed in the area including the bendable area BDA of the display panel. The third barrier structure BS3 may be disconnected from the fourth barrier structure BS4. That is, a broken area may be defined in an area from which the organic insulating material is removed and which is disposed between the third barrier structure BS3 and the fourth barrier structure BS4.

The fourth barrier structure BS4 may have a structure in which a (1-4)th layer 252c and a (2-4)th layer 266c are vertically stacked. For example, the (1-4)th layer 252c may be made of the same material as that of the second planarization layer 252 and may be formed in the same process as the process for forming the second planarization layer 252. The (2-4)th layer 266c may be made of the same material as that of and be formed in the same process as that of the organic insulating structure 266. The (1-4)th layer 252c may cover the end portions of the inorganic insulating material layers 205, 213, 214, 216, 242, and 218 so as not to be exposed to the outside. The (2-4)th layer 266c may cover the upper surface and side surfaces of the (1-4)th layer 252c.

The outer dam O-DM may be disposed between the inner dam I-DM and the fourth barrier structure BS4. The outer dam O-DM may have a structure in which a lower layer 251o, an middle layer 252o, and an upper layer 266o are vertically stacked. The outer dam O-DM may include an organic insulating material. For example, the lower layer 251o of the outer dam O-DM may be made of the same material as that of and be formed in the same process as that of the first planarization layer 251. The middle layer 252o may be made of the same material as that of and be formed in the same process as that of the second planarization layer 252. The upper layer 266o of the outer dam O-DM may be made of the same material as that of and be formed in the same process as that of the organic insulating structure 266. The lower layer 251o of the outer dam O-DM may cover the end portion of the signal line 256 so as not to be exposed.

The outer dam O-DM and the fourth barrier structure BS 4 may be spaced apart from each other while a separation space is defined therebetween. The third interlayer insulating layer 218 among the plurality of inorganic insulating material layers 205, 213, 214, 216, 242, and 218 may be partially exposed through the separation space defined between the outer dam O-DM and the fourth barrier structure BS4.

The inorganic insulating structure 276 including the inorganic insulating material and the touch insulating structure 280 may be vertically stacked on each of the first barrier structure BS1, the inner dam I-DM, the outer dam O-DM, and the fourth barrier structure BS4. Accordingly, a portion of the third interlayer insulating layer 218 among the multiple inorganic insulating material layers 205, 213, 214, 216, 242, and 218 as exposed through the separation space disposed between the outer dam O-DM and the fourth barrier structure BS4 may be in contact with the inorganic insulating structure 276.

The inorganic insulating structure 276 and the touch insulating structure 280 may be covered with the first touch protective layer 290. For example, the end portions of the inorganic insulating structure 276 and the touch insulating structure 280 disposed in the second zone BZ2 may be covered with the first touch protective layer 290. The second touch protective layer 295 may be disposed on the first touch protective layer 290. The second touch protective layer 295 may cover the first touch protective layer 290. The second touch protective layer 295 may cover the portion of the substrate 201 exposed through the separation space between the lower corner end 200BC_E of the lower corner area of the display panel 200 and the fourth barrier structure BS4.

Each of the first touch protective layer 290 and the second touch protective layer 295 may include an organic insulating material.

The inorganic insulating structure 276 and the touch insulating structure 280 may cover an entirety of the display area AA and an entire area of the first zone BZ1 of the non-display area NAA and may extend onto and along a partial area of the second zone BZ2. For example, the inorganic insulating structure 276 and the touch insulating structure 280 may cover both opposing side surfaces and an upper surface of the fourth barrier structure BS 4. For example, each of both opposing side surfaces of the fourth barrier structure BS 4 may be an inclined side surface.

Accordingly, in the lower corner area of the display panel 200 including the lower corner end 200BC_E of the display panel 200, all of the first barrier structure BS1, the inner dam I-DM, the outer dam O-DM, and the fourth barrier structure BS 4 including the organic insulating material may be covered with the inorganic insulating material. That is, since all of the films including the organic insulating material are covered with the film including the inorganic insulating material, a structure robust against moisture penetration may be achieved.

In addition, an area between the lower corner end 200BC_E of the lower corner area of the display panel 200 and the fourth barrier structure BS4 may include an area from which the organic insulating layer has been removed. Accordingly, the moisture penetration path may be blocked by removing the organic insulating layer that may be damaged during the dry etching process on the inorganic insulating structure 276. Accordingly, the situation in which the moisture flows along the organic insulating layer to the area where the signal line 256 is disposed to corrode the signal line 256 may be suppressed. Further, a film lift-off defect may be prevented from occurring. Accordingly, a signal or voltage for the operation of the display area AA may be stably provided, such that product reliability may be improved.

In addition, the portion of the third interlayer insulating layer 218 exposed through the separation space defined between the outer dam O-DM and the fourth barrier structure BS 4 is in contact with the inorganic insulating structure 276, such that a passage through which moisture flows may be blocked.

In addition, the fourth barrier structure BS 4 is disposed in the outer area of the display panel 200 close to the lower corner end 200BC_E of the lower corner area of the display panel 200. The fourth barrier structure BS 4 is covered with the inorganic insulating material. Thus, a structure robust against external damage may be implemented.

Accordingly, the corrosion of the signal line may be suppressed, the defect rate of the display device may be lowered, and thus production energy required for the production of the display device may be reduced, thereby reducing the emission of greenhouse gas.

A display device according to one aspect and various embodiments of the present disclosure may be described as follows.

One aspect of the present disclosure provides a display device comprising: a substrate; a display area disposed on the substrate; a non-display area including a first area surrounding an outer side of the display area and a second area disposed on one side of the display area; a bendable area disposed in the second area; a lower corner area extending from the first area of the non-display area to the bendable area and including a lower corner end ; and a plurality of structures disposed spaced apart from each other in the lower corner area, wherein one of the plurality of structures is disposed with a spacing from the lower corner end of the lower corner area by a gap.

In accordance with some embodiments, a signal line is disposed in the first area or second areas of the non-display area, wherein an end portion of the signal line is covered with at least one of the plurality of structures.

In accordance with some embodiments, the signal line includes a low-potential power (VSS) line.

In accordance with some embodiments, the non-display area includes: a first zone adjacent to the display area; and a second zone disposed outwardly of the first zone and surrounding the first zone.

In accordance with some embodiments, a plurality of inorganic insulating material layers are vertically stacked on the substrate and in the non-display area, wherein one of the plurality of structures covers an end portion of the stack of the inorganic insulating material layers.

In accordance with some embodiments, the plurality of structures include: a first barrier structure disposed in the first zone, wherein the first barrier structure among the plurality of structures is closest to the display area; and a blocking structure disposed on a boundary area between the first zone and the second zone.

In accordance with some embodiments, the blocking structure covers the end portion of the stack of the inorganic insulating material layers.

In accordance with some embodiments, the plurality of structures further include a plurality of dams disposed between the first barrier structure and the blocking structure in the plan view, wherein the plurality of dams include: an inner dam spaced apart from one side of the first barrier structure; and an outer dam spaced apart from one side of blocking structure and positioned outwardly of the inner dam.

In accordance with some embodiments, the plurality of structures further include a third barrier structure disposed in the bendable area, wherein the third barrier structure and the blocking structure are spaced from each other such that a disconnected region is defined therebetween.

In accordance with some embodiments, a signal line is disposed in the first zone, wherein the outer dam covers an end portion of the signal line.

In accordance with some embodiments, the display device further comprises: an inorganic insulating structure covering the plurality of structures; and a touch insulating structure disposed on the inorganic insulating structure, wherein the inorganic insulating structure covers both side surfaces and an upper surface of the blocking structure.

In accordance with some embodiments, the display device further comprises: a first touch protective layer disposed on the inorganic insulating structure; and a second touch protective layer disposed on the first touch protective layer, wherein each of the first touch protective layer and the second touch protective layer includes an organic insulating material.

In accordance with some embodiments, the display device further comprises: an inorganic insulating structure covering the plurality of structures; a touch insulating structure disposed on the inorganic insulating structure; a first touch protective layer disposed on the inorganic insulating structure; and a second touch protective layer disposed on the first touch protective layer, wherein the spacing exposes a surface of the substrate, and the exposed surface of the substrate contacts the second touch protection layer.

In accordance with some embodiments, each of the plurality of structures includes an organic insulating material.

In accordance with some embodiments, wherein a spacing is disposed between the outer dam and the blocking structure, wherein the spacing exposing a portion of a stack of the plurality of inorganic insulating material layers, and wherein an uppermost one of the plurality of inorganic insulating material layers in the spacing contacts the inorganic insulating structure..

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a display area disposed on the substrate;
a non-display area including a first area surrounding an outer side of the display area and a second area disposed on one side of the display area;
a bendable area disposed in the second area;
a lower corner area extending from the first area of the non-display area to the bendable area and including a lower corner end; and
a plurality of structures disposed spaced apart from each other in the lower corner area,
wherein one of the plurality of structures is spaced from the lower corner end of the lower corner area.

2. The display device of claim 1, wherein a signal line is disposed in the first area or second area of the non-display area, and
wherein an end portion of the signal line is covered with at least one of the plurality of structures.

3. The display device of claim 2, wherein the signal line includes a low-potential power (VSS) line.

4. The display device of claim 1, wherein the non-display area includes:
a first zone adjacent to the display area; and
a second zone disposed outwardly of the first zone and surrounding the first zone.

5. The display device of claim 4, wherein a plurality of inorganic insulating material layers are vertically stacked on the substrate and in the non-display area, and
wherein one of the plurality of structures covers an end portion of the stack of the inorganic insulating material layers.

6. The display device of claim 5, wherein the plurality of structures include:
a first barrier structure disposed in the first zone, wherein the first barrier structure among the plurality of structures is closest to the display area; and
a blocking structure disposed on a boundary area between the first zone and the second zone.

7. The display device of claim 6, wherein the blocking structure covers the end portion of the stack of the inorganic insulating material layers.

8. The display device of claim 6, wherein the plurality of structures further include a plurality of dams disposed between the first barrier structure and the blocking structure in the plan view,
wherein the plurality of dams include:
an inner dam spaced apart from one side of the first barrier structure; and
an outer dam spaced apart from one side of the blocking structure and positioned outwardly of the inner dam.

9. The display device of claim 6, wherein the plurality of structures further include a third barrier structure disposed in the bendable area, and
wherein the third barrier structure and the blocking structure are spaced from each other such that a disconnected region is defined therebetween.

10. The display device of claim 8, wherein a signal line is disposed in the first zone, and
wherein the outer dam covers an end portion of the signal line.

11. The display device of claim 6, wherein the display device further comprises:
an inorganic insulating structure covering the plurality of structures; and
a touch insulating structure disposed on the inorganic insulating structure,
wherein the inorganic insulating structure covers both side surfaces and an upper surface of the blocking structure.

12. The display device of claim 11, wherein the display device further comprises:
a first touch protective layer disposed on the inorganic insulating structure; and
a second touch protective layer disposed on the first touch protective layer,
wherein each of the first touch protective layer and the second touch protective layer includes an organic insulating material.

13. The display device of claim 9, wherein the display device further comprises:
an inorganic insulating structure covering the plurality of structures;
a touch insulating structure disposed on the inorganic insulating structure;
a first touch protective layer disposed on the inorganic insulating structure; and
a second touch protective layer disposed on the first touch protective layer,
wherein a spacing between the blocking structure and the third barrier structure exposes a surface of the substrate, and the exposed surface of the substrate contacts the second touch protection layer.

14. The display device of claim 13, wherein each of the plurality of structures includes an organic insulating material.

15. The display device of claim 8, wherein a spacing is disposed between the outer dam and the blocking structure,
wherein the spacing exposing a portion of a stack of the plurality of inorganic insulating material layers, and
wherein an uppermost one of the plurality of inorganic insulating material layers in the spacing contacts the inorganic insulating structure.
